(19) United States
(12) Patent Application Publication
(10) Pub. No.: US 2026/0122819 A1
(43) Pub. Date: Apr. 30, 2026

(54) SHIELDED CABLE SUPPORT STRUCTURE FOR CONTROL SYSTEM COMPONENTS

(71) Applicant: Rockwell Automation Asia Pacific Business Center Pte. Ltd., Singapore (SG)

(72) Inventor: Soon Seng Kang, Singapore (SG)

(21) Appl. No.: 18/930,728

(22) Filed: Oct. 29, 2024

(51) Int. Cl. H05K 7/14; H01R 13/635

(52) U.S. Cl. CPC H05K 7/1468; H01R 13/635; H05K 7/1484

(57) ABSTRACT

A system may include a terminal block having a plurality of terminals configured to receive one or more wires. The system may also include an input/output (I/O) device with a circuit configured to electrically couple to the one or more wires via the terminal block. Further, the system may include a structure including a body with a portion configured to couple to the terminal block, and one or more spring clamps coupled to the body. The one or more spring clamps may be configured to secure the one or more wires placed therein, where the one or more wires are routed to one or more terminals of the plurality of terminals via the one or more spring clamps.

### BACKGROUND

The present disclosure relates generally to the field of automation control systems, such as those used in industrial and commercial settings. More particularly, embodiments of the present disclosure relate to techniques for providing, accessing, configuring, operating, or interfacing with input/output (I/O) devices that are used for coupling and interaction with an automation controller.

Automation controllers may include special purpose computers used for controlling industrial automation and the like. Under the direction of stored programs, a processor of the automation controller examines a series of inputs (e.g., electrical input signals to the automation controller) reflecting the status of a controlled process and changes outputs (e.g., electrical output signals from the automation controller) based on analysis and logic for affecting control of the controlled process. The stored control programs may be continuously executed in a series of execution cycles, executed periodically, or executed based on events. The inputs received by the automation controller from the controlled process and the outputs transmitted by the automation controller to the controlled process are normally passed through one or more I/O devices, which may include components of an automation control system that may serve as an electrical interface between the automation controller and the controlled process.

Some I/O devices include a base that may couple the I/O device with a bus bar or the like, a terminal block for communicatively coupling the I/O device with field devices, an I/O module that includes circuitry for performing communication functions and/or logic operations, and the like. The terminal blocks of the I/O devices may couple to wires or other electrical components to interface with field devices. During operation, the I/O devices may experience electromagnetic interference due to a large number of electrical input and output signals traversing the electrical components, which may lead to signal noise and unexpected control issues. As a result, shielded cables may be utilized to reduce the signal noise received and the electromagnetic interference generated by the electrical input and output signals. The shielded cables may be grounded in order to reflect electromagnetic radiation and to redirect signal noise to ground. It may be useful to provide features for supporting and grounding shielded cables for use in industrial automation processes.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a system may include a terminal block having a plurality of terminals configured to receive one or more wires. The system may also include an input/output (I/O) device with a circuit configured to electrically couple to the one or more wires via the terminal block. Further, the system may include a structure with a body having a portion configured to couple to the terminal block, and one or more spring clamps coupled to the body. The one or more spring clamps may be configured to secure the one or more wires placed therein, such that the one or more wires are routed to one or more terminals of the plurality of terminals via the one or more spring clamps.

### BRIEF DESCRIPTION OF THE DRAWINGS

These and other features, aspects, and advantages of the present invention will become better understood when the following detailed description is read with reference to the accompanying drawings in which like characters represent like parts throughout the drawings, wherein:

FIG. 1 illustrates an example industrial automation system employed by a food manufacturer, in accordance with an embodiment;

FIG. 2 illustrates a diagrammatical representation of an exemplary control and monitoring system that may be employed in any suitable industrial automation system, in accordance with an embodiment;

FIG. 3 is a perspective view of a plurality of input/output (I/O) devices connected to an I/O adapter, in accordance with an embodiment;

FIG. 4 illustrates an exemplary shielded cable, in accordance with an embodiment;

FIG. 5 is a perspective view of an exemplary shielded cable support structure coupled to a terminal block for use with the exemplary I/O device, in accordance with an embodiment;

FIG. 6 is a perspective view of an exemplary shielded cable support structure assembly for use with the exemplary I/O device, in accordance with an embodiment;

FIG. 7 is a partially exploded-view of the exemplary shielded cable support structure assembly of FIG. 6, in accordance with an embodiment; and

FIG. 8 is a perspective view of the exemplary shielded cable support structure of FIG. 6 in use securing four shielded cables, in accordance with an embodiment.

### DETAILED DESCRIPTION

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” “the,” and “said” are intended to mean that there are one or more of the elements. The terms “comprising,” “including,” and “having” are intended to be inclusive and mean that there may be additional elements other than the listed elements. As used herein, the terms “container nodes,” “host devices,” and “container hosts” may be used interchangeably. One or more specific embodiments of the present embodiments described herein will be described below. In an effort to provide a concise description of these embodiments, all features of an actual implementation may not be described in the specification.

As mentioned above, terminal blocks may couple to wires or other electrical components to allow input/output (I/O) devices to communicatively couple to field devices, such as sensors, actuators, and the like. In some embodiments, the I/O terminal blocks may couple to shielded cables. Shielded cables include conductive shields which may reduce the noise experienced and caused by I/O signals. During operation, the shields are grounded to reflect electromagnetic radiation and reduce signal noise. Accordingly, shielded cables may be used with I/O devices to reduce a number of unexpected control issues associated with electromagnetic interference and to increase the sensitivity of inputs and outputs received and transmitted by automation controllers. However, traditional techniques for securing and grounding shielded cables (e.g., cable clamps) may only accommodate a single shielded cable, and thus, may be unsuitable for use with terminal blocks that facilitates access to multiple cables. Further, existing methods for grounding multiple shielded cables (e.g., a grounding bus bar) may involve greater clearance between respective I/O devices and cable enclosures (e.g., ducts, runways, channels, trays, covers, etc.). Thus, it may be challenging to utilize shielded cables in control processes with limited space and/or complex space constraints.

Accordingly, the present disclosure is related to systems and methods for supporting and grounding shielded cables for use with I/O devices. In some embodiments, a shielded cable support structure may include a main body with a coupling element (e.g., a tab, insert, etc.) that mechanically couples to a terminal block of an I/O device. The support structure may also include one or more spring clamps fastened to the main body for receiving shielded cables. The main body may include one or more components extending in between the sides of the one or more spring clamps to divide the spring clamps into two or more wiring routes. Thus, features of the main body may increase the number of shielded cables each of the one or more spring clamps may receive.

The main body may also include features (e.g., slots, indents, etc.) to secure the shielded cables to the support structure, such as indentations or grooves for cable ties to interface with. Accordingly, the support structure may prevent the shielded cables from shifting during operation, thereby helping to maintain proper connection between the shielded cables and the terminal block.

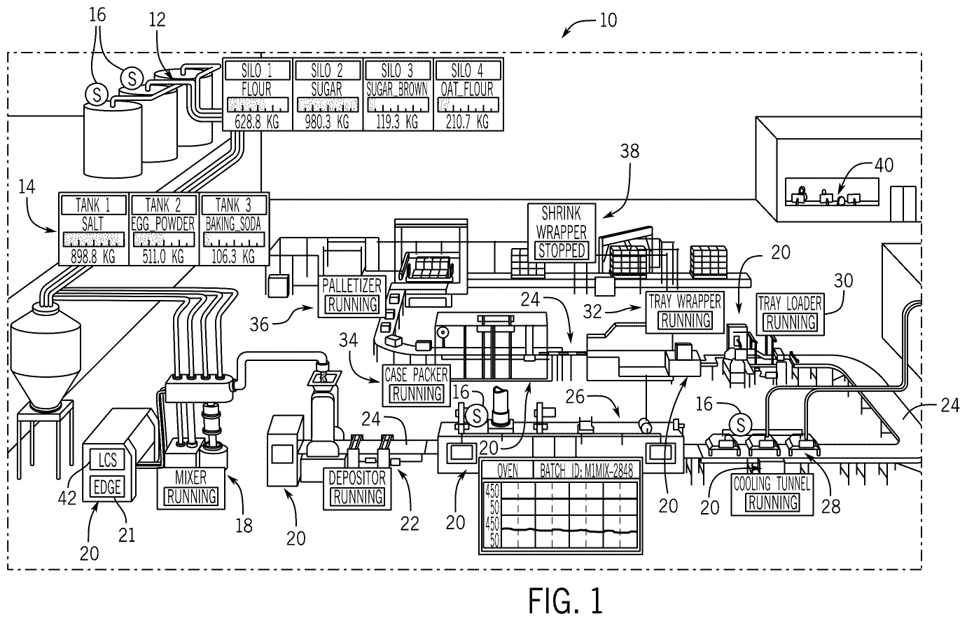

When shielded cables are installed into the terminal block via the support structure, the shields of the respective shielded cables may terminate at the spring clamps for grounding. The spring clamps and main body may be formed out of one or more conductive materials (e.g., stainless steel, carbon steel, alloy steel, etc.). In this way, the entire support structure may be grounded, thereby grounding each of the shielded cables without the need for a separate grounding bus bar or individually grounding the shields of each shielded cable (e.g., by dressing each shield into a pigtail and/or soldering a wire to each shield). As a result, the support structure may provide an improved system and method for grounding shielded cables and securing shielded cables to terminal blocks of I/O devices. Additional details regarding the present embodiments described above will be detailed below with reference to FIGS. 1-8.

By way of introduction, FIG. 1 illustrates an example industrial automation system 10 employed by a food manufacturer. It should be noted that although the example industrial automation system 10 of FIG. 1 is directed at a food manufacturer, the present embodiments described herein may be employed within any suitable industry, such as automotive, mining, hydrocarbon production, manufacturing, and the like. The following brief description of the example industrial automation system 10 employed by the food manufacturer is provided herein to help facilitate a more comprehensive understanding of how the embodiments described herein may be applied to industrial devices to significantly improve the operations of the respective industrial automation system. As such, the embodiments described herein should not be limited to be applied to the example depicted in FIG. 1.

Referring now to FIG. 1, the example industrial automation system 10 for a food manufacturer may include silos 12 and tanks 14. The silos 12 and the tanks 14 may store different types of raw material, such as grains, salt, yeast, sweeteners, flavoring agents, coloring agents, vitamins, minerals, and preservatives. In some embodiments, sensors 16 may be positioned within or around the silos 12, the tanks 14, or other suitable locations within the industrial automation system 10 to measure certain properties, such as temperature, mass, volume, pressure, humidity, and the like.

The raw materials may be provided to a mixer 18, which may mix the raw materials together according to a specified ratio. The mixer 18 and other machines in the industrial automation system 10 may employ certain industrial automation devices 20 to control the operations of the mixer 18 and other machines. The industrial automation devices 20 may include controllers, input/output (I/O) modules, motor control centers, motors, human machine interfaces (HMIs), operator interfaces, contactors, starters, sensors 16, actuators, conveyors, drives, relays, protection devices, switchgear, compressors, sensor, actuator, firewall, network switches (e.g., Ethernet switches, modular-managed, fixed-managed, service-router, industrial, unmanaged, etc.) and the like.

The mixer 18 may provide a mixed compound to a depositor 22, which may deposit a certain amount of the mixed compound onto conveyor 24. The depositor 22 may deposit the mixed compound on the conveyor 24 according to a shape and amount that may be specified to a control system for the depositor 22. The conveyor 24 may be any suitable conveyor system that transports items to various types of machinery across the industrial automation system 10. For example, the conveyor 24 may transport deposited material from the depositor 22 to an oven 26, which may bake the deposited material. The baked material may be transported to a cooling tunnel 28 to cool the baked material, such that the cooled material may be transported to a tray loader 30 via the conveyor 24. The tray loader 30 may include machinery that receives a certain amount of the cooled material for packaging. By way of example, the tray loader 30 may receive 25 ounces of the cooled material, which may correspond to an amount of cereal provided in a cereal box.

A tray wrapper 32 may receive a collected amount of cooled material from the tray loader 30 into a bag, which may be sealed. The tray wrapper 32 may receive the collected amount of cooled material in a bag and seal the bag using appropriate machinery. The conveyor 24 may transport the bagged material to case packer 34, which may package the bagged material into a box. The boxes may be transported to a palletizer 36, which may stack a certain number of boxes on a pallet that may be lifted using a forklift or the like. The stacked boxes may then be transported to a shrink wrapper 38, which may wrap the stacked boxes with shrink-wrap to keep the stacked boxes together while on the pallet. The shrink-wrapped boxes may then be transported to storage or the like via a forklift or other suitable transport vehicle.

To perform the operations of each of the devices in the example industrial automation system 10, the industrial automation devices 20 may be used to provide power to the machinery used to perform certain tasks, provide protection to the machinery from electrical surges, prevent injuries from occurring with human operators in the industrial automation system 10, monitor the operations of the respective device, communicate data regarding the respective device to a supervisory control system 40, and the like. In some embodiments, each industrial automation device 20 or a group of industrial automation devices 20 may be controlled using a local control system 42. The local control system 42 may include receive data regarding the operation of the respective industrial automation device 20, other industrial automation devices 20, user inputs, and other suitable inputs to control the operations of the respective industrial automation device(s) 20.

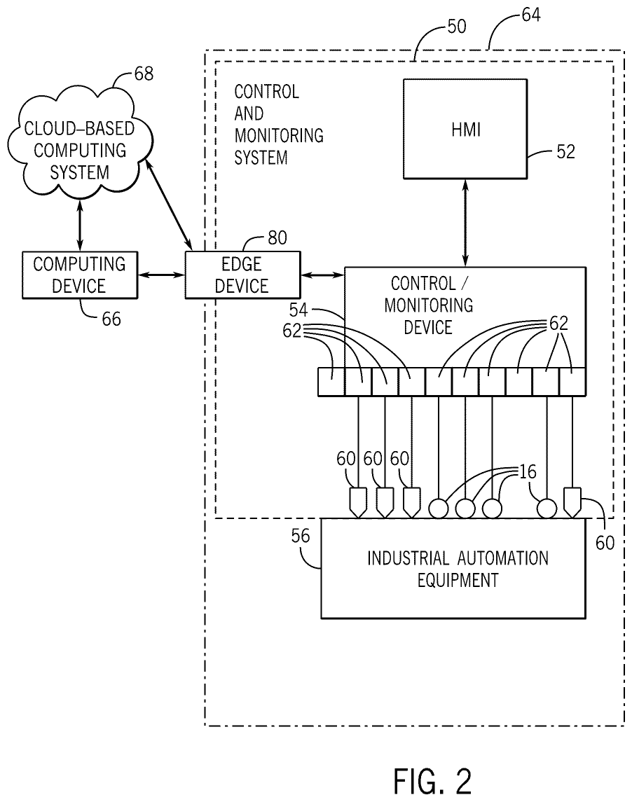

By way of example, FIG. 2 illustrates a diagrammatical representation of an exemplary control and monitoring system 50 that may be employed in any suitable industrial automation system 10, in accordance with embodiments presented herein. In FIG. 2, the control and monitoring system 50 is illustrated as including a human machine interface (HMI) 52 and a control/monitoring device 54 or automation controller adapted to interface with devices that may monitor and control various types of industrial automation equipment 56. By way of example, the industrial automation equipment 56 may include the mixer 18, the depositor 22, the conveyor 24, the oven 26, and the other pieces of machinery described in FIG. 1.

It should be noted that the HMI 52 and the control/monitoring device 54, in accordance with embodiments of the present techniques, may be facilitated by the use of certain network strategies. Indeed, an industry standard network may be employed, such as DeviceNet, to enable data transfer. Such networks permit the exchange of data in accordance with a predefined protocol, and may provide power for operation of networked elements.

As discussed above, the industrial automation equipment 56 may take many forms and include devices for accomplishing many different and varied purposes. For example, the industrial automation equipment 56 may include machinery used to perform various operations in a compressor station, an oil refinery, a batch operation for making food items, a mechanized assembly line, and so forth. Accordingly, the industrial automation equipment 56 may comprise a variety of operational components, such as electric motors, valves, actuators, temperature elements, pressure sensors, or a myriad of machinery or devices used for manufacturing, processing, material handling, and other applications.

Additionally, the industrial automation equipment 56 may include various types of equipment that may be used to perform the various operations that may be part of an industrial application. For instance, the industrial automation equipment 56 may include electrical equipment, hydraulic equipment, compressed air equipment, steam equipment, mechanical tools, protective equipment, refrigeration equipment, power lines, hydraulic lines, steam lines, and the like. Some example types of equipment may include mixers, machine conveyors, tanks, skids, specialized original equipment manufacturer machines, and the like. In addition to the equipment described above, the industrial automation equipment 56 may be made up of certain automation devices 20, which may include controllers, input/output (I/O) modules or devices, motor control centers, motors, human machine interfaces (HMIs), operator interfaces, contactors, starters, sensors 16, actuators, drives, relays, protection devices, switchgear, compressors, firewall, network switches (e.g., Ethernet switches, modular-managed, fixed-managed, service-router, industrial, unmanaged, etc.) and the like.

In certain embodiments, one or more properties of the industrial automation equipment 56 may be monitored and controlled by certain equipment for regulating control variables used to operate the industrial automation equipment 56. For example, the sensors 16 and actuators 60 may monitor various properties of the industrial automation equipment 56 and may adjust operations of the industrial automation equipment 56, respectively.

In some cases, the industrial automation equipment 56 may be associated with devices used by other equipment. For instance, scanners, gauges, valves, flow meters, and the like may be disposed on industrial automation equipment 56. Here, the industrial automation equipment 56 may receive data from the associated devices and use the data to perform their respective operations more efficiently. For example, a controller (e.g., control/monitoring device 54) of a motor drive may receive data regarding a temperature of a connected motor and may adjust operations of the motor drive based on the data.

In certain embodiments, the industrial automation equipment 56 may include a communication component that enables the industrial equipment 56 to communicate data between each other and other devices. The communication component may include a network interface that may enable the industrial automation equipment 56 to communicate via various protocols such as Ethernet/IP®, ControlNet®, DeviceNet®, or any other industrial communication network protocol. Alternatively, the communication component may enable the industrial automation equipment 56 to communicate via various wired or wireless communication protocols, such as Wi-Fi, mobile telecommunications technology (e.g., 2G, 3G, 4G, 5G, LTE), Bluetooth®, near-field communications technology, and the like.

The sensors 16 may be any number of devices adapted to provide information regarding process conditions. The actuators 60 may include any number of devices adapted to perform a mechanical action in response to a signal from a controller (e.g., the control/monitoring device 54). The sensors 16 and actuators 60 may be utilized to operate the industrial automation equipment 56. Indeed, they may be utilized within process loops that are monitored and controlled by the control/monitoring device 54 and/or the HMI 52. Such a process loop may be activated based on process inputs (e.g., input from a sensor 16) or direct operator input received through the HMI 52. As illustrated, the sensors 16 and actuators 60 are in communication with the control/monitoring device 54. Further, the sensors 16 and actuators 60 may be assigned a particular address in the control/monitoring device 54 and receive power from the control/monitoring device 54 or attached modules.

Input/output (I/O) modules or devices 62 may be added or removed from the control and monitoring system 50 via expansion slots, bays or other suitable mechanisms in accordance with embodiments described herein. In certain embodiments, the I/O modules 62 may be included to add functionality to the control/monitoring device 54, or to accommodate additional process features. For instance, the I/O modules 62 may communicate with new sensors 16 or actuators 60 added to monitor and control the industrial automation equipment 56. It should be noted that the I/O modules 62 may communicate directly to sensors 16 or actuators 60 through hardwired connections or may communicate through wired or wireless sensor networks, such as Hart or IOLink.

Generally, the I/O modules 62 serve as an electrical interface to the control/monitoring device 54 and may be located proximate or remote from the control/monitoring device 54, including remote network interfaces to associated systems. In such embodiments, data may be communicated with remote modules over a common communication link, or network, wherein modules on the network communicate via a standard communications protocol. Many industrial controllers can communicate via network technologies such as Ethernet (e.g., IEEE802.3, TCP/IP, UDP, Ethernet/IP, and so forth), ControlNet, DeviceNet or other network protocols (Foundation Fieldbus (H1 and Fast Ethernet) Modbus TCP, Profibus) and also communicate to higher level computing systems.

In the illustrated embodiment, several of the I/O modules 62 may transfer input and output signals between the control/monitoring device 54 and the industrial automation equipment 56. As illustrated, the sensors 16 and actuators 60 may communicate with the control/monitoring device 54 via one or more of the I/O modules 62 coupled to the control/monitoring device 54.

In certain embodiments, the control/monitoring system 50 (e.g., the HMI 52, the control/monitoring device 54, the sensors 16, the actuators 60, the I/O modules 62) and the industrial automation equipment 56 may make up an industrial automation application 64. The industrial automation application 64 may involve any type of industrial process or system used to manufacture, produce, process, or package various types of items. For example, the industrial applications 64 may include industries such as material handling, packaging industries, manufacturing, processing, batch processing, the example industrial automation system 10 of FIG. 1, and the like.

In certain embodiments, the control/monitoring device 54 may be communicatively coupled to a computing device 66 and a cloud-based computing system 68. In this network, input and output signals generated from the control/monitoring device 54 may be communicated between the computing device 66 and the cloud-based computing system 68. Although the control/monitoring device 54 may be capable of communicating with the computing device 66 and the cloud-based computing system 68, as mentioned above, in certain embodiments, the control/monitoring device 54 (e.g., local computing system 42) may perform certain operations and analysis without sending data to the computing device 66 or the cloud-based computing system 68.

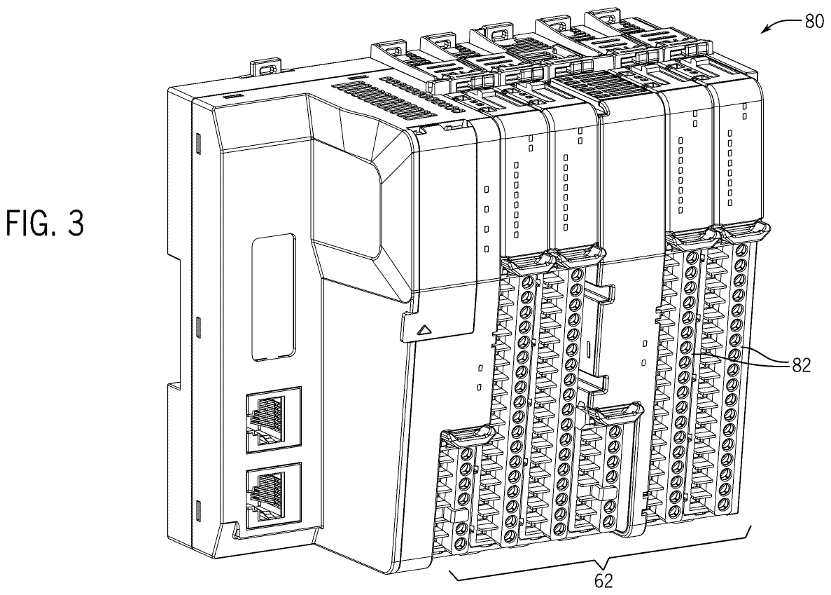

With the foregoing in mind, as mentioned above, the I/O modules 62 may be coupled to the control/monitoring device 54 via bays, electrical slots, expansion slots, and the like. By way of example, FIG. 3 illustrates a perspective view of a I/O module system 80 that may include a number of I/O modules 62. As illustrated, each I/O module 62 may include terminal blocks 82 that may couple to wires or other electrical components. In some embodiments, each I/O module 62 may include a housing to enclose or surround circuitry (e.g., a circuit device) for performing communication functions and/or logic operations. The housing may be composed of plastic, metal, or other suitable material to protect the circuitry. The circuitry may include a number of electrical connectors (e.g., trace ends, board-to-board connectors) that may electrically couple the control/monitoring device 54, the industrial automation equipment 56, or any other devices coupled to the I/O module system 80. For example, the terminal blocks 82 may include terminals that electrically couple to the electrical connectors of the circuitry. In this way, the I/O modules 62 may receive signals from devices via the wires or other electrical components coupled to the terminal blocks.

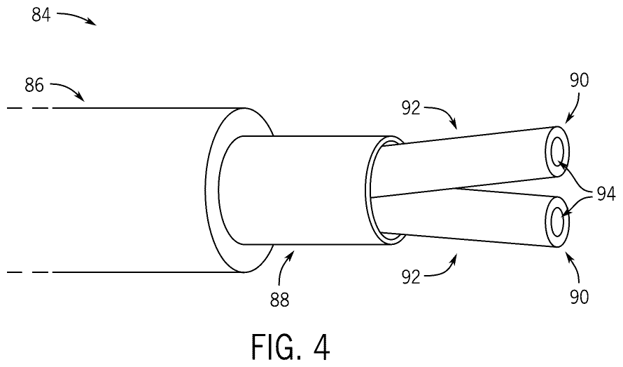

In some embodiments, the terminal blocks 82 may couple to shielded cables or wires, such as a shielded cable 84 shown in FIG. 4. The shielded cable 84 may include a sheath or jacket 86, a shield 88, and one or more internal wires 90. The jacket 86 may be a nonconductive conductive material (e.g., plastic) that protects the internal components of the shielded cable 84 (e.g., the shield 88, internal wires 90, etc.) from moisture, high and/or low temperatures, chemicals, mechanical wear (e.g., pinching, tearing, etc.), and the like. The shield 88 may be conductive foil (e.g., a thin layer of aluminum), braided shielding (e.g., a woven mesh of copper wires), and the like, or a combination thereof. During operation, the jacket 86 may be stripped (e.g., removed) from a portion of the shielded cable 84, to expose the shield 88. An end of the exposed shield 88 may be grounded to allow the shield 88 to reflect electromagnetic radiation and conduct noise to ground. Thus, the shield 88 may reduce the amount of electromagnetic interference generated and received by signals traversing the internal wires 90, thereby decreasing signal noise and increasing the sensitivity of the signals. The internal wires 90 may include insulation 92 to protect their respective conductive cores 94. The insulation 92 may be a nonconductive material (e.g., plastic) that protects the conductive cores 94 from similar environmental factors as the jacket 86 (e.g., moisture, extreme temperatures, etc.), while physically and electrically isolating the conductive cores 94 from each other. The conductive cores 94 may be solid or stranded copper, or any other suitable conductor, and may transport electrical signals. While FIG. 4 shows two internal wires 90, the shielded cable 84 may include more or fewer internal wires (e.g., 1, 3, 4, 5, etc.). During operation, each of the internal wires 90 may extend past the grounded, exposed shield 88, and may mechanically and electrically couple to terminals of the terminal blocks 82. For example, the insulation 92 may be stripped from the end of the internal wires 90 and the conductive cores 94 may be inserted into and coupled to respective terminals of the terminal blocks 82.

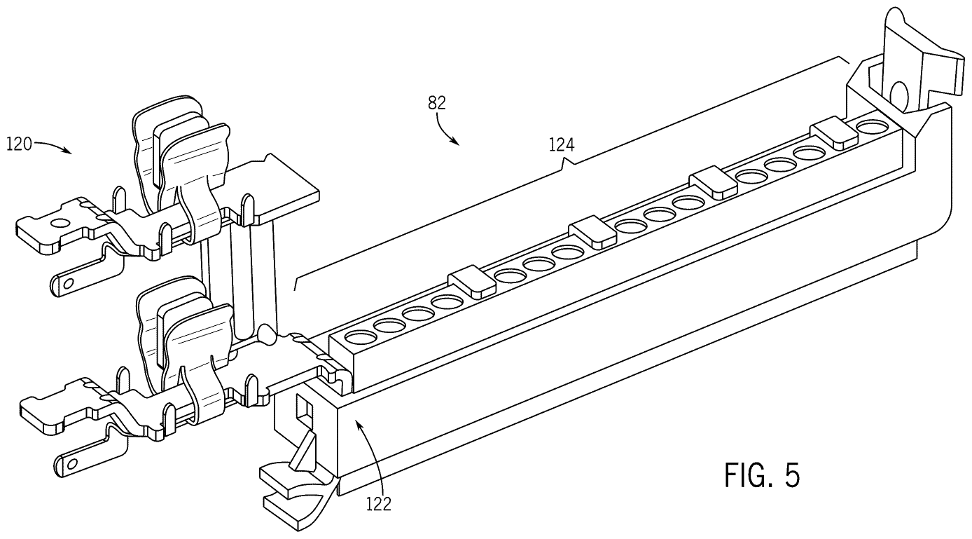

As discussed above, it may be challenging to couple terminal blocks 82 and shielded cables 84, as existing methods may accommodate a single shielded cable and/or may benefit from greater clearance between the I/O module system 80 and respective cable enclosures (e.g., ducts, runways, channels, trays, covers, etc.). Accordingly, a shielded cable support structure 120 may be coupled to a terminal block 82, as shown in FIG. 5, to decrease the space needed to ground each shielded cable 84, to increase the ease of installing shielded cables 84 (e.g., reduce the time it takes, reduce the number of components needed, etc.), to help maintain connections between the shielded cables 84 and the terminals of the terminal block 82 (e.g., reduce shifting, minimize the effects of vibrations, etc.), and the like. For example, the shielded cable support structure 120 may couple to the terminal block 82 via an aperture or slot 122 adjacent to the terminals 124 of the terminal block 82.

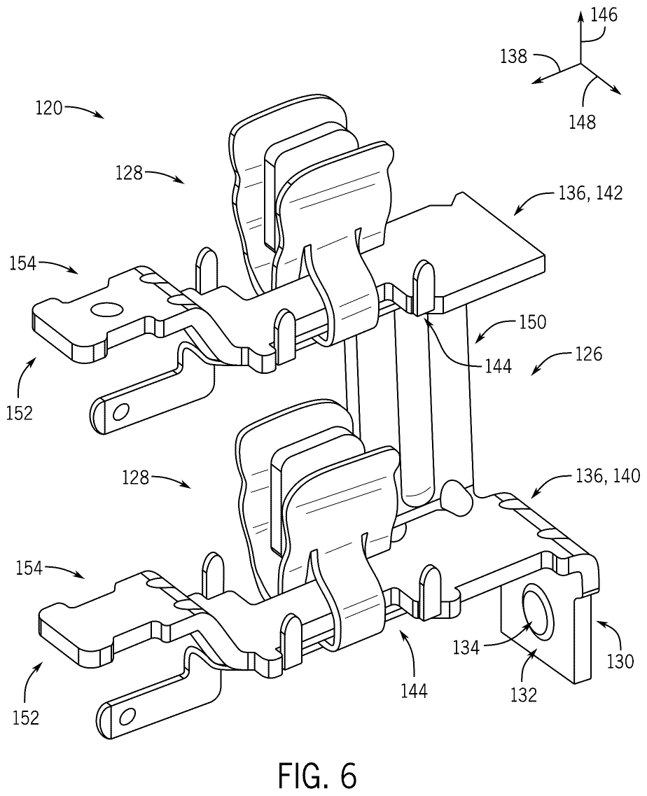

Referring closely to FIG. 6, in some embodiments, the shielded cable support structure 120 may include a main body 126 and two spring clamps 128. The main body 126 may include a portion or coupling element (e.g., a tab, insert, etc.) 130 that may be inserted or positioned within the slot 122 of the terminal block 82 (shown in FIG. 5). As will be appreciated, the coupling element 130 may have dimensions (e.g., length, width, height) that corresponds to dimensions of the slot 122, such that the coupling element 130 securely fits within the slot 122. By way of example, the coupling element 130 may have a rectangular or square shape that matches the dimensions of the slot 122. In some embodiments, when placed in the slot 122, the coupling element 130 may be affixed or mechanically secured within the slot 122 by mechanical fasteners or the like. In some embodiments, the coupling element 130 may be affixed or retained in the slot 122 using an interference-fit technique or arrangement or other suitable manner. For example, a side or face 132 of the coupling element 130 may have a protrusion 134 with substantially similar or the same dimensions (e.g., diameter) of an indentation, cutout, or the like, in a corresponding side or face of the slot 122. In this way, the protrusion 134 may sit in or interface with a feature of the terminal block 82 to prevent movement and securely fasten the shielded cable support structure 120 to the terminal block 82.

In some embodiments, the main body 126 of the support structure 120 may include two panels or segments 136 extending in a first direction 138 (e.g., a horizontal, longitudinal, etc. direction). Each of the segments 136 (e.g., a first segment 140, a second segment 142) may include indentations or notches 144 for receiving the spring clamps 128. The first segment 140 and the second segment 142 may be offset from one another in/along one or more directions (e.g., the first direction 138, a second direction 146, a third direction 148, etc.) via an element, such as an additional member 150 of the main body 126. For example, the additional member 150 may extend between a side of the first segment 140 to a corresponding side of the second segment, along the second direction 146 (e.g., the vertical direction). In this way, multiple shield cables 84 may be inserted into or held by the spring clamps 128 without tangling or otherwise interfering with each other.

Further, the segments 136 may each include support elements 152. The support elements 152 may each extend at a certain angle and height from the segments 136 such that shielded cables 84 held in the spring clamps 128 may contact and/or interface with the support elements 152. Additionally, the support elements 152 may include indentations or grooves 154 to receive cable ties or any other suitable fasteners to secure the shielded cables 84 to the support structure 120 via the support elements 152. In this way, the support elements 152 may reduce movement (e.g., shifting, vibrations) of the shielded cables 84 during operation, and thus, may help maintain proper electrical and mechanical connections between the shielded cables 84 and the terminal blocks 82.

While the illustrative embodiment includes a main body 126 with two segments 136 for receiving two spring clamps 128, it should be appreciated that the support structure 120 may include more or fewer segments 136 for receiving more or fewer spring clamps 128. For example, in some embodiments, the main body 126 may include the coupling element 130 and the first segment 140 for receiving a spring clamp 128, without including the additional member 150 and the second segment 142. Further, in some embodiments, one or more additional segments may be coupled to the first segment 140 and/or the second segment 142 in substantially the same way as the second segment is shown coupled to the first segment in FIG. 6 (e.g., via an additional member extending between the first and/or second segment and the one or more additional segments). Additionally, while FIG. 6 shows the components of the main body 126 (e.g., the coupling element 130, segments 136, additional member 150, support elements 152, etc.) integrally formed with one another as a single piece component, in some embodiments, some or all of the components of the main body may be mechanically coupled to one another via one or more fasteners (e.g., screws, bolts, etc.).

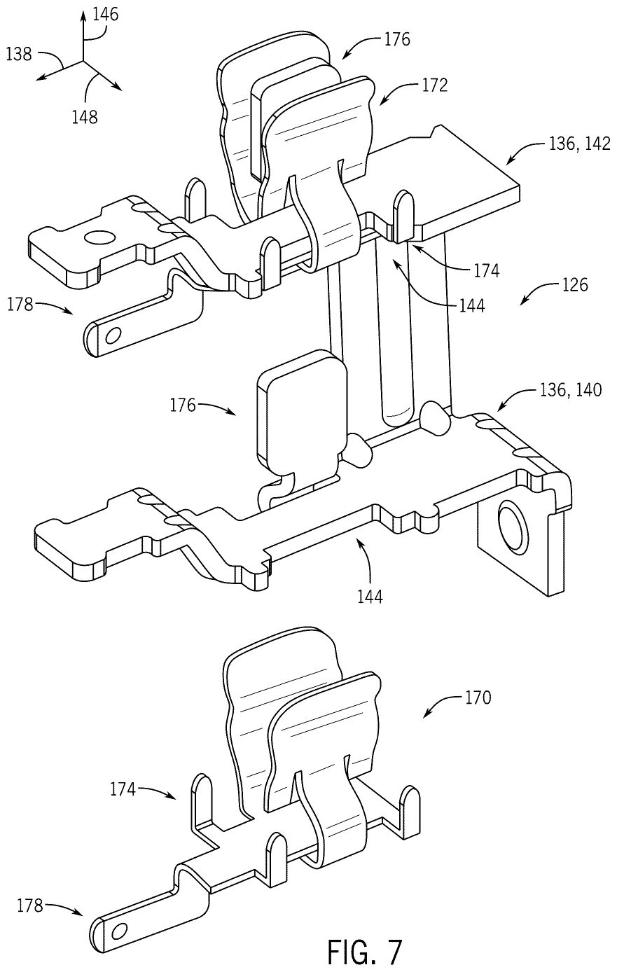

FIG. 7 illustrates a partially exploded-view of the shielded cable support structure assembly 120 with a first spring clamp 170 aligned with the first segment 140 of the main body 126 and a second spring clamp 172 coupled to the second segment 142 of the main body 126. During operation, the first spring clamp 170 may be positioned or inserted into the notches 144 of the first segment 140 to mechanically couple to the main body 126, in substantially the same way as the second spring clamp 172 is shown coupled to the second segment 142. The spring clamps 128 (e.g., the first spring clamp 170 and the second spring clamp 172) may each include a number of protrusions or tabs 174 (e.g., 2, 4, etc.) that may be bent or angled to apply pressure on the first segment 140 or the second segment 142, respectively, to securely fasten the spring clamps 128 to the main body 126. In some embodiments, the spring clamps 128 may not include the bendable tabs 174 and may be coupled to the main body 126 using any other suitable fasteners or fastening technique (e.g., screw, bolt, adhesive, interference-fit technique, etc.).

The first segment 140 and the second segment 142 may each include a divider component 176. Each divider component 176 may be positioned in between sides of the respective spring clamp 128 (e.g., the first spring clamp 170 or the second spring clamp 172) defining a channel to receive a shielded cable 84. Further, the divider components 176 may extend from the main body 126 in a direction (e.g., the second direction 146, the vertical direction, etc.) substantially parallel with the sides of the spring clamps 128, thereby partitioning the channel (e.g., the space between the sides of the spring clamps 128) into two wiring routes. In this way, the divider components 176 may increase the number of shielded cables 84 each of the spring clamps 128 may receive, without substantially increasing the size of the support structure 120. While the illustrative embodiment shows one divider component 176 for each spring clamp 128, it should be noted that the segments 136 of the main body 126 may include less or more divider components 176 (e.g., 0, 2, 3, etc. divider components) defining less or more wiring routes within the channels of the spring clamps 128 (e.g., 1, 3, 4, etc. wiring routes).

The spring clamps 128 may each include grounding components 178 with dimensions (e.g., length, width, height) corresponding to crimp sleeves, or any other suitable component, that may be used for grounding the shielded cables 84. The spring clamps 128 and the main body 126 may each be made out of conductive materials (e.g., stainless steel, carbon steel, alloy steel, aluminum, etc.). Accordingly, the entire support structure 120 may be grounded via the grounding components 178 of the spring clamps 128. Thus, the support structure 120 may eliminate the need to individually ground each shielded cable 84 through time-consuming methods, such as dressing the shields 88 of each cable 84 into a pigtail and/or soldering a wire to each shield 88 for grounding, and may require less space than a grounding bus bar.

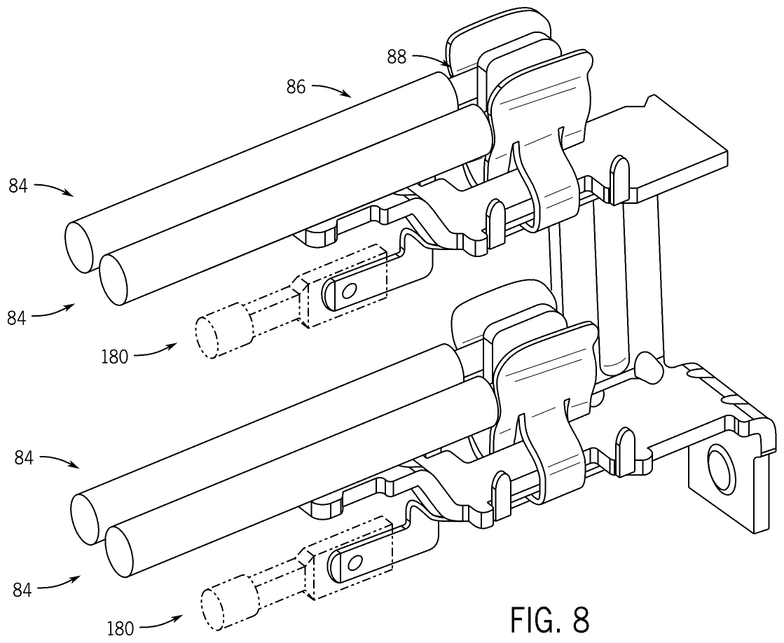

FIG. 8 illustrates the support structure 120 with shielded cables 84 installed. As shown, the jackets 86 of the shielded cables 84 may be stripped (e.g., removed) from a portion of the shielded cables 84, such that the shields 88 contact the sides of the spring clamps 128 for grounding. Crimping sleeves 180 may be positioned on the grounding components 178 of the spring clamps 128 to ground the support structure 120, and thus, the shields 88. The shields 88 may terminate at the spring clamps 128, and the one or more internal wires 90 (not shown) of each shielded cable 84 may extend past the spring clamps 128 to mechanically and electrically couple to terminals of the terminal block 82. In this way, the support structure 120 may decrease the space needed to ground each shielded cable 84, increase the ease of installing shielded cables 84 (e.g., reduce the time it takes, reduce the number of components needed, etc.), and help maintain proper connections between the shielded cables 84 and the terminals of the terminal block 82 (e.g., reduce shifting, minimize the effects of vibrations, etc.).

The techniques presented and claimed herein are referenced and applied to material objects and concrete examples of a practical nature that demonstrably improve the present technical field and, as such, are not abstract, intangible, or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

While only certain features of the embodiments have been illustrated and described herein, many modifications and changes will occur to those skilled in the art. It is, therefore, to be understood that the appended claims are intended to cover all such modifications and changes as fall within the true spirit of the present embodiments describe herein.

1. A system, comprising:
a terminal block comprising a plurality of terminals configured to receive one or more wires;
an input/output (I/O) device comprising a circuit configured to electrically couple to the one or more wires via the terminal block; and
a structure comprising:
a body comprising a portion configured to couple to the terminal block; and
one or more spring clamps coupled to the body, wherein the one or more spring clamps are configured to secure the one or more wires placed therein, wherein the one or more wires are routed to one or more terminals of the plurality of terminals via the one or more spring clamps.

2. The system of claim 1, wherein the terminal block comprises an aperture configured to receive the portion.

3. The system of claim 2, wherein the portion comprises a protrusion configured to interface with an indentation within the aperture.

4. The system of claim 1, wherein the body comprises:
a first segment configured to receive a first spring clamp of the one or more spring clamps; and
a second segment configured to receive a second spring clamp of the one or more spring clamps, wherein the first segment and the second segment are coupled to each other via an element, and wherein the first segment is offset from the second segment in a direction.

5. The system of claim 4, wherein the first segment comprises a support element extending from the first segment, and wherein the support element is configured to support a first wire of the one or more wires and comprises one or more grooves configured to secure the first wire to the support element using a fastener.

6. The system of claim 4, wherein the first segment comprises a divider component configured to extend into a channel within the first spring clamp, and wherein a first wire of the one or more wires is configured to be positioned adjacent to the divider component and inside the channel.

7. The system of claim 1, wherein the body and the one or more spring clamps comprise a conductive material.

8. The system of claim 1, wherein the one or more spring clamps comprise one or more grounding components configured to couple the structure to ground when the one or more spring clamps are coupled to the body.

9. The system of claim 1, wherein each spring clamp of the one or more spring clamps comprises one or more protrusions configured to mechanically couple a respective spring clamp to the body.

10. An assembly, comprising:
a body comprising a portion configured to couple to a terminal block of an input/output (I/O) device; and
a spring clamp configured to couple to a segment of the body, wherein the segment comprises a divider component configured to extend into a channel within the spring clamp, wherein a wire is configured to be positioned adjacent to the divider component and inside the channel and routed to a terminal of the terminal block via the spring clamp.

11. The assembly of claim 10, wherein the body and the spring clamp comprise a conductive material.

12. The assembly of claim 10, wherein the spring clamp comprises a grounding component configured to couple the assembly to ground when the spring clamp is coupled to the segment.

13. The assembly of claim 10, wherein the segment comprises a support element extending from the segment, and wherein the support element is configured to support the wire and comprises one or more grooves configured to secure the wire to the support element using a fastener.

14. The assembly of claim 10, wherein the spring clamp comprises one or more protrusions configured to mechanically couple the spring clamp to the segment.

15. A method, comprising:
coupling a support structure to a terminal block, wherein the support structure comprises:
a body comprising a portion configured to couple to the terminal block; and
one or more spring clamps configured to couple to the body and secure one or more wires placed therein;
coupling a first spring clamp of the one or more spring clamps to a segment of the body, wherein the segment comprises a divider component configured to extend into a channel within the first spring clamp;
positioning a first wire of the one or more wires adjacent to the divider component and inside the channel; and
inserting the first wire into a terminal of the terminal block, wherein the first wire is routed to the terminal via the first spring clamp, and wherein the first wire is configured to electrically couple to a circuit of an input/output (I/O) device via the terminal block.

16. The method of claim 15, wherein the body and the one or more spring clamps comprise a conductive material.

17. The method of claim 15, comprising coupling the support structure to ground via a grounding component of the first spring clamp.

18. The method of claim 15, wherein coupling the support structure to the terminal block comprises inserting a protrusion of the portion into an indentation within an aperture of the terminal block.

19. The method of claim 15, comprising securing the first wire to a support element extending from the segment, wherein the support element comprises one or more grooves configured to secure the first wire to the support element using a fastener.

20. The method of claim 15, wherein the first spring clamp comprises one or more protrusions configured to mechanically couple the first spring clamp to the segment.
